(19) United States
(12) Patent Application Publication
(10) Pub. No.: US 2025/0220867 A1
(43) Pub. Date: Jul. 3, 2025

(54) ELECTROMAGNETIC WAVE- AND MAGNETIC FIELD-ABSORBING- AND-SHIELDING SHEET, AND ELECTRONIC DEVICE COMPRISING SAME

(71) Applicant: AMOSENSE CO.,LTD, Cheonan-si, Chungcheongnam-do (KR)

(72) Inventor: Kil Jae JANG, Cheonan-si, Chungcheongnam-do (KR)

(73) Assignee: AMOSENSE CO.,LTD, Cheonan-si, Chungcheongnam-do (KR)

(21) Appl. No.: 18/686,670

(22) PCT Filed: Aug. 26, 2022
(86) PCT No.: PCT/KR2022/012815

§ 371 Date: Mar. 21, 2025

(30) Foreign Application Priority Data
Aug. 27, 2021 (KR) 10-2021-0113798

(51) Int. Cl. H05K 9/00

(52) U.S. Cl. CPC H05K 9/0088

(57) ABSTRACT

An electromagnetic wave- and magnetic field-absorbing-and-shielding sheet according to an exemplary embodiment of the present invention is implemented by comprising: an electromagnetic wave- and magnetic field-absorbing-and-shielding unit having a plurality of magnetic layers stacked to shield electromagnetic waves and magnetic fields; and an electromagnetic wave-absorbing adhesive member, which is arranged between the adjacent magnetic layers to absorb electromagnetic waves that have transmitted the magnetic layers or are reflected from the magnetic layers, and fixes the adjacent magnetic layers. Accordingly, together with an electromagnetic wave- and magnetic field-shielding function, the present invention has a function of enabling most of the electromagnetic waves reflected during shielding to be absorbed to minimize influence on surrounding electronic components, electronic devices, or a user of the electronic devices, caused by electromagnetic waves reflected during shielding and the magnetic field shielding, and thus can be widely applied to various electronic devices and the like.

### CROSS REFERENCE TO RELATED APPLICATIONS

This application is a 35 U.S.C. § 371 National Stage of International Patent Application No. PCT/KR2022/012815, filed Aug. 26, 2022, claiming benefit from Korean Patent Application No. 10-2021-0113798, filed Aug. 27, 2021, the disclosures of which are incorporated herein in their entirety by reference, and priority is claimed to each of the foregoing.

### TECHNICAL FIELD

The present invention relates to an electromagnetic wave- and magnetic field-absorbing-and-shielding sheet, and more particularly, to an electromagnetic wave- and magnetic field-absorbing-and-shielding sheet and an electronic device including the same.

### BACKGROUND

Although modern society benefits greatly from the rapid development of electrical communication technology, the number of IT devices such as computers and communication devices increases exponentially in the process of expanding informatization, and concerns about problems of disability caused by unnecessary electromagnetic waves are increasing as the frequency bandwidth of use increases and frequencies becomes higher. The problem of unnecessary electromagnetic waves is inevitable for devices using electricity, and various noise measures have been developed and applied from the design stage to suppress them as much as possible.

However, in the case of radioactive noise, there is a limit to noise reduction through shielding, and as the shielded radioactive noise hardly disappears and is reflected, there is a problem that the impact on the components present inside the unshielded system cannot be solved.

In addition, as electronic devices become light, thin, compact, and miniaturized, and various components inside them are highly integrated, the effects of interference due to electromagnetic waves reflected after being shielded in the first place are becoming a bigger problem.

Meanwhile, recent electronic devices are equipped with magnetic materials inside the device for various reasons, such as the adoption of speakers and microphone-related components, or to have structural foldable characteristics, and the magnetic field formed by such magnetic materials also has a negative impact on adjacent electronic components, and such a problem has become even greater in recent high-performance portable devices where electronic components are highly integrated.

Therefore, it is urgent to take measures to prevent the arrival of electromagnetic waves or magnetic fields to users who use electronic devices that are interfered with the functions of various components in electronic devices or generate electromagnetic waves or magnetic fields.

### SUMMARY OF THE INVENTION

The present invention has been devised to solve the above problems, and is directed to providing an electromagnetic wave- and magnetic field-absorbing-and-shielding sheet and an electronic device including the same capable of minimizing interference with electronic components due to reflections generated in the process of shielding electromagnetic waves and magnetic fields or influence on a user's human body.

In order to solve the above problems, the present invention provides an electromagnetic wave- and magnetic field-absorbing-and-shielding sheet, including an electromagnetic wave- and magnetic field-absorbing-and-shielding unit, having: a plurality of magnetic layers stacked to shield electromagnetic waves and magnetic fields; and an electromagnetic wave-absorbing adhesive member, which is arranged between the adjacent magnetic layers so as to absorb electromagnetic waves that have transmitted the magnetic layers or are reflected from the magnetic layers, and fixes the adjacent magnetic layers.

According to an exemplary embodiment of the present invention, the plurality of magnetic layers may include one or more of a soft magnetic alloy ribbon sheet, a soft magnetic alloy ribbon sheet split into multiple pieces, and a soft magnetic alloy ribbon sheet with at least one eddy current reduction pattern part formed.

In addition, the eddy current reduction pattern part may be a crack part in which a magnetic material constituting a magnetic layer in a predetermined region is divided into a plurality of pieces, or may be a penetration part penetrating the predetermined region.

In addition, the electromagnetic wave-absorbing adhesive member may be made of an electromagnetic wave-absorbing adhesive layer in which an electromagnetic wave absorber is dispersed in a binder matrix or may be an electromagnetic wave-absorbing double-sided tape having, on both surfaces of a substrate, an electromagnetic wave-absorbing adhesive layer in which an electromagnetic wave absorber is dispersed in a binder matrix.

In addition, the electromagnetic wave-absorbing adhesive member may be an electromagnetic wave-absorbing double-sided tape in which an adhesive layer is provided on both surfaces of an electromagnetic wave-absorbing substrate.

In addition, the adhesive layer may be an electromagnetic wave-absorbing adhesive layer in which an electromagnetic wave absorber is dispersed in a binder matrix.

In addition, the electromagnetic wave-absorbing substrate may be a metal foil, a polymer substrate in which a metal film is arranged on one or both surfaces, or a polymer substrate in which an electromagnetic wave absorber is dispersed therein.

In addition, the electromagnetic wave-absorbing substrate may have a plurality of mountain-shaped or pyramid-shaped protrusions on one or both surfaces.

In addition, the electromagnetic wave absorber may include any one or more of dielectric powder, magnetic powder, and conductor powder.

In addition, the thickness of the magnetic layer may be 15 to 35 μm, and the thickness of the electromagnetic wave-absorbing adhesive member may be 3 to 50 μm.

In addition, the present invention provides an antenna module, including an antenna unit equipped with at least one antenna; and the electromagnetic wave- and magnetic field-absorbing-and-shielding sheet according to the present invention arranged on one surface of the antenna unit.

In addition, the present invention provides an electronic device including the electromagnetic wave- and magnetic field-absorbing-and-shielding sheet according to the present invention.

### Advantageous Effects

The electromagnetic wave- and magnetic field-absorbing-and-shielding sheet according to the present invention has, together with an electromagnetic wave- and magnetic field-shielding function, a function of enabling most of the electromagnetic waves reflected during shielding to be absorbed to minimize influence on surrounding electronic components, electronic devices, or a user of the electronic devices, caused by the electromagnetic waves reflected during shielding and the magnetic field shielding, and thus can be widely applied to various electronic devices and the like.

### BRIEF DESCRIPTION OF THE DRAWINGS

FIG. 1 is a cross-sectional view of an electromagnetic wave- and magnetic field-absorbing-and-shielding sheet according to an exemplary embodiment of the present invention.

FIGS. 2 to 4 are enlarged cross-sectional views of an electromagnetic wave- and magnetic field-absorbing-and-shielding unit included in various exemplary embodiments of the present invention.

FIG. 5 is a perspective view of an electromagnetic wave- and magnetic field-absorbing-and-shielding sheet according to an exemplary embodiment of the present invention.

FIG. 6 is an enlarged view of an eddy current reduction pattern part included in FIG. 5.

FIG. 7 is an enlarged cross-sectional view taken along the boundary line X-X′ in FIG. 6.

FIGS. 8 to 11 are a plan view and a partial enlarged view of an electromagnetic wave- and magnetic field-absorbing-and-shielding sheet according to various exemplary embodiments of the present invention.

FIG. 12 is an exploded perspective view of an antenna module according to an exemplary embodiment of the present invention.

FIGS. 13 to 15 are plan views of an antenna module according to various exemplary embodiments of the present invention.

### DETAILED DESCRIPTION OF THE EMBODIMENTS

Hereinafter, exemplary embodiments of the present invention will be described in detail so that those of ordinary skill in the art can readily implement the present invention with reference to the accompanying drawings. The present invention may be embodied in many different forms and is not limited to the embodiments set forth herein. In the drawings, parts unrelated to the description are omitted for clarity of description of the present invention, and same or similar reference numerals denote same elements.

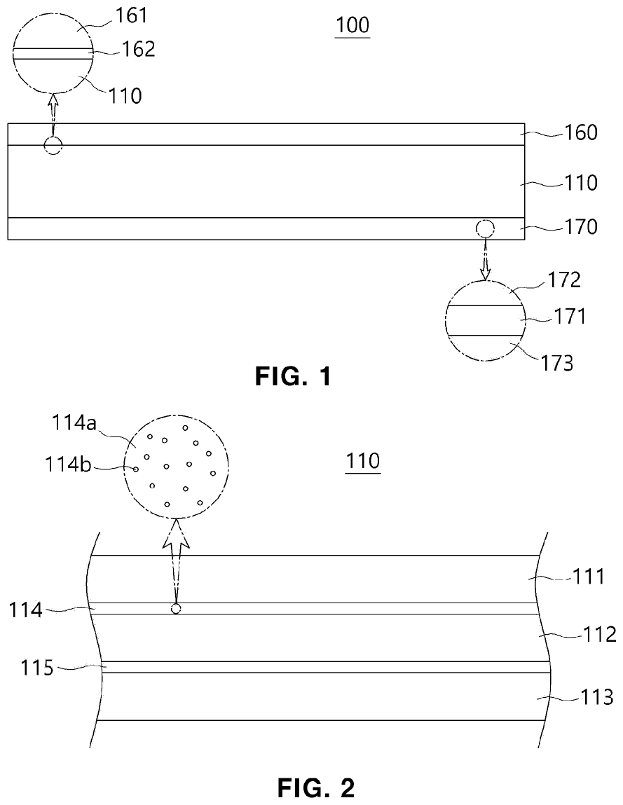

Describing with reference to FIGS. 1 to 2, the electromagnetic wave- and magnetic field-absorbing-and-shielding sheet 100 according to an exemplary embodiment of the present invention includes an electromagnetic wave- and magnetic field-absorbing-and-shielding unit 110, and may further include a protection part 160 provided on one surface of the electromagnetic wave- and magnetic field-absorbing-and-shielding unit 110 and an attachment part 170 provided on the other surface of the electromagnetic wave- and magnetic field-absorbing-and-shielding unit 110 facing the one surface.

The electromagnetic wave- and magnetic field-absorbing-and-shielding unit includes a plurality of magnetic layers 111, 112, 113 stacked to absorb and shield electromagnetic waves and magnetic fields; and an electromagnetic wave-absorbing adhesive member 114, 115, which is arranged between the adjacent magnetic layers 111, 112, 113 so as to absorb electromagnetic waves that have transmitted the magnetic layers 111, 112, 113 or are reflected from the magnetic layers 111, 112, 113, and fixes the adjacent magnetic layers 111, 112, 113.

The plurality of magnetic layers 111, 112, 113 may be made of a known magnetic material capable of shielding electromagnetic waves or magnetic fields emitted from an electromagnetic wave generating source and a magnetic field generating source. For example, the magnetic layers 111, 112, 113 may be soft magnetic alloy ribbon sheets, and specifically, may be soft magnetic alloy ribbon sheets containing transition metals such as iron, nickel, and cobalt, and as a more specific example, may include one or more of Fe—Si—B, Fe—Si—B—Cu, Fe—Si—B—C, Fe—Si—B—C—Cu Fe—B—Cu, Fe—B—C—Cu, Fe—B—C—Cu—Nb, and alloys in which some or all of Fe is replaced with Ni or Co. In addition, in the case of the soft magnetic alloy ribbon sheet above, it may be a soft magnetic alloy containing amorphous or nanocrystalline grains.

In addition, the magnetic layers 111, 112, 113 may be stacked in the thickness direction, and for example, two or three magnetic layers may be provided, but are not limited thereto and may be appropriately changed in consideration of desired shielding level, design conditions, and the like.

In addition, each of the multiple magnetic layers 111, 112, 113 may have a thickness of 15 to 35 μm, and if the thickness of each magnetic layer exceeds 35 μm, it is difficult to implement a thinned absorbing-and-shielding sheet, and the flexibility of the absorbing-and-shielding sheet may decrease. Furthermore, if the thickness is less than 15 μm, handling will deteriorate, and there is a high risk of damage in the magnetic layer due to the manufacturing process of the absorbing-and-shielding sheet, the process of attaching it to the attachment target surface of the attachment target, or the external force applied during use, and because of this, there is a risk that the initially set shielding performance may change.

In addition, the magnetic layers 111, 112, 113 may be a ribbon sheet itself without cracks, as shown in FIG. 2, but some or all of the plurality of magnetic layers may be one or more of a soft magnetic alloy ribbon sheet split into a plurality of pieces and a soft magnetic alloy ribbon sheet including at least one eddy current reduction pattern part. In other words, to increase the flexibility of electromagnetic wave- and magnetic field-absorbing-and-shielding sheets, to improve shielding performance in a specific frequency band, to focus the magnetic field toward a specific component, such as an antenna, or to improve the inductance of the antenna and minimize loss and heat generation due to eddy currents, as illustrated in FIG. 4, it may be advantageous that each of the plurality of magnetic layers 111′, 112′, 113′ provided in the electromagnetic wave- and magnetic field-absorbing-and-shielding unit 110″ has cracks 131, which are a plurality of split pieces. In this case, the crack 131 may be provided in the form of a first crack 131A having no gap between magnetic pieces or a second crack 131B having a gap between magnetic pieces.

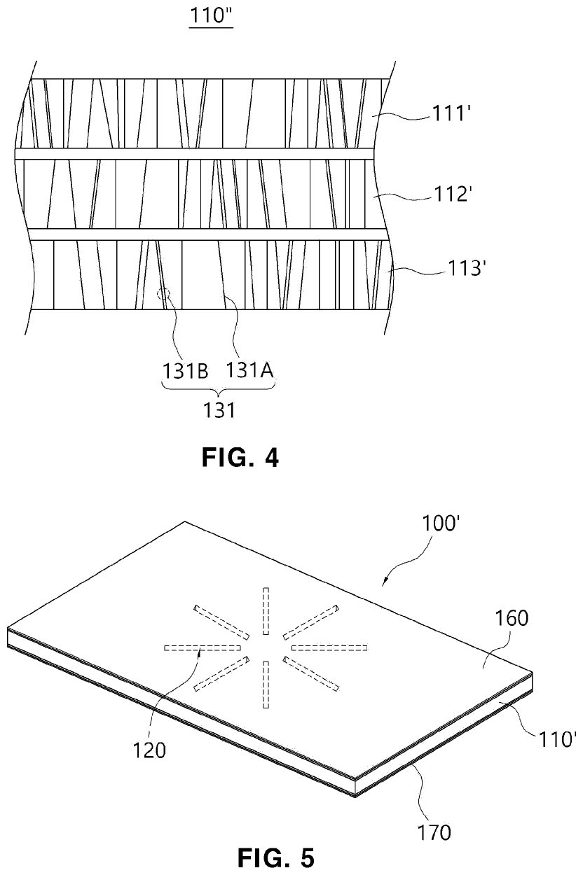

Alternatively, as illustrated in FIG. 5, the magnetic layers 111, 112, 113 may be soft magnetic alloy ribbon sheets including at least one eddy current reduction pattern part 120. The eddy current reduction pattern part 120 increases the overall resistance of the electromagnetic wave- and magnetic field-absorbing-and-shielding unit 110′, thereby minimizing loss due to eddy current or influence on the antenna due to heat generation and eddy current.

The eddy current reduction pattern part 120 may have any configuration capable of increasing the overall resistance of the electromagnetic wave- and magnetic field-absorbing-and-shielding unit 110′. In addition, the eddy current reduction pattern part 120 may be formed to occupy any one region of the inner regions of the electromagnetic wave- and magnetic field-absorbing-and-shielding unit 110′. In addition, the shape of the eddy current reduction pattern part 120 occupying the above one region is not limited, and may be, for example, a slit shape with a predetermined length and width, but is not limited thereto, and may be formed to occupy a predetermined area in a shape such as ‘+’, ‘×’, ‘*’, ‘⊥’ or “·”.

In addition, the number of eddy current reduction pattern parts 120 may be one or more, and the size may be 0.1 to 0.4 mm in width when it is slit-shaped, but it may be provided in an appropriate number and size in consideration of the structure, shape, desired eddy current reduction level, antenna size, and the like. In addition, the eddy current reduction pattern part 120 may be partially formed in a partial region of the entire region of the electromagnetic wave- and magnetic field-absorbing-and-shielding unit 110′.

In addition, if the article placed in one surface of the electromagnetic wave- and magnetic field-absorbing-and-shielding sheet 100′ is an antenna, the eddy current reduction pattern part 120 may be placed on some of the regions corresponding to the antenna, and may be placed in various locations in consideration of the shape and position of the antenna. For example, in the case of an antenna including a hollow portion having a predetermined area and a pattern part surrounding the hollow portion in the central portion, it may be formed at a position corresponding to a region in which the pattern part is placed.

In addition, the eddy current reduction pattern part 120 may be, for example, composed of a crack part 130 in which a magnetic material constituting the magnetic layers in a predetermined region inside the electromagnetic wave- and magnetic field-absorbing-and-shielding unit 110′ is divided into a plurality of pieces, or a penetration part 140 penetrating the predetermined region.

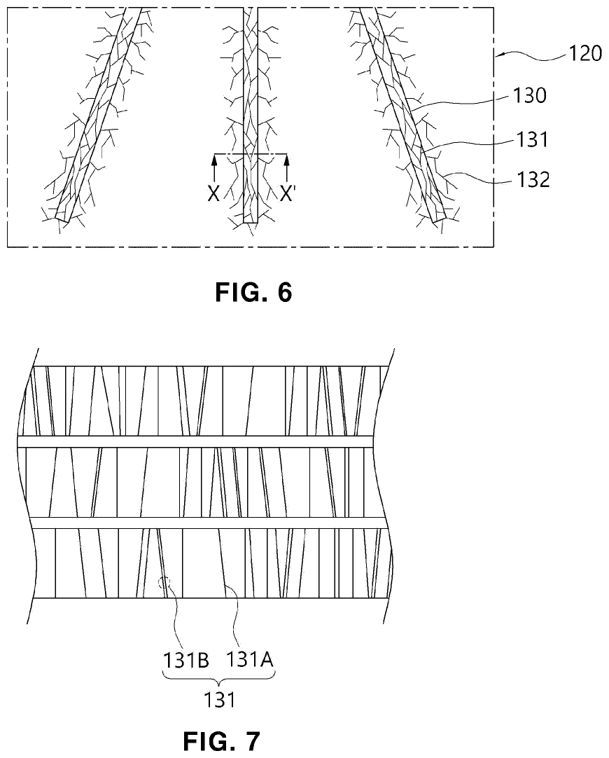

First, the crack part 130 among various forms of the eddy current reduction pattern part 120 will be described. As shown in FIGS. 6 and 7, the crack part 130 is formed by splitting a magnetic material existing in a predetermined region into a plurality of pieces, and may include a crack 131. In this case, the remaining part of the entire region of the electromagnetic wave- and magnetic field-absorbing-and-shielding unit 110 except for the crack part 130 may not be separated into a plurality of pieces.

Here, the crack 131 included in the crack part 130 may be formed by splitting a plurality of magnetic layers 111, 112, 113 by applying an external force to the laminate in which the plurality of magnetic layers 111, 112, 113 are stacked through a pressing member or the like. In this case, a plurality of pieces separated by the crack 131 may be disconnected from each other, but may maintain a state 131A in contact with each other, or a fine space 131B may be formed between adjacent pieces separated. Meanwhile, the fine space 131B may be distinguished from the penetration part 140 in that it has a very fine width compared to the penetration part 140 to be described later, and is formed in any one magnetic layer 111, 112, 113.

Meanwhile, cracks 131 are not formed only within a border dividing the predetermined region described above in the electromagnetic wave- and magnetic field-absorbing-and-shielding unit 110′, but additionally, a plurality of microcracks 132 may be formed to extend outside the predetermined region border defining the eddy current reduction pattern part 120. That is, when pressed through a pressing member to form the crack part 130 in the electromagnetic wave- and magnetic field-absorbing-and-shielding unit 110′, microcracks 132 extending outside the region extending from the predetermined region in addition to the desired region may be formed together.

Meanwhile, as another example of the crack part 130 including the crack 131, the crack part 130 may include a plurality of regular cracks formed in a predetermined shape and a plurality of irregular cracks derived from the plurality of regular cracks.

As described above, the crack part 130 including the crack 131 may increase resistance as the magnetic material is separated into a plurality of pieces, thereby reducing an eddy current.

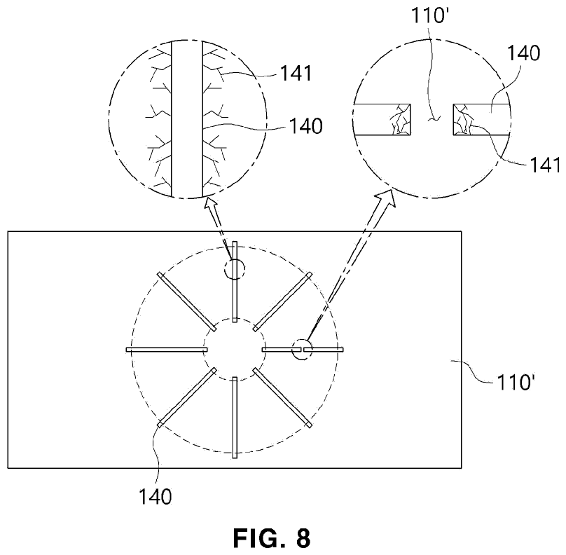

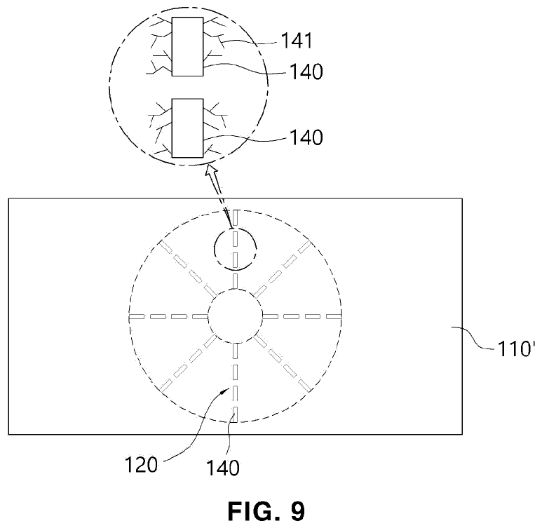

Next, the penetration part 140, another example of the eddy current reduction pattern part 120, is formed to penetrate two surfaces facing the thickness direction of the electromagnetic wave- and magnetic field-absorbing-and-shielding unit 110, as shown in FIGS. 8 and 9. In this case, a plurality of microcracks 141 formed to extend outward from the border of the region occupying the penetration part 140 due to external force applied in the process of forming the penetration part 140 may be further included, and the microcracks 141 may help reduce eddy currents together with the penetration part 140.

In this case, the plurality of microcracks 141 formed from the penetration part 140 may or may not be connected to each other. In addition, only some of the plurality of microcracks 141 may be connected to each other. Accordingly, the electromagnetic wave- and magnetic field-absorbing-and-shielding sheet 100′ according to an exemplary embodiment of the present invention may increase overall resistance through the penetration part 140 and the plurality of microcracks 141 formed in the electromagnetic wave- and magnetic field-absorbing-and-shielding unit 110′, thereby reducing eddy currents.

As a non-limiting example of the penetration part 140, as shown in FIG. 8, the penetration part 140 may be formed in a slit shape having a length longer than a width.

As another example, as shown in FIG. 9, in the case of the penetration part 140, a plurality of penetration parts 140 may be linearly arranged in one direction at a predetermined interval therebetween so that the plurality of penetration parts 140 form a dotted line shape as a whole.

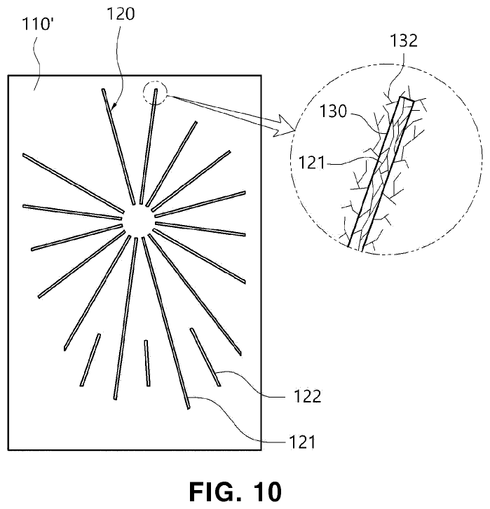

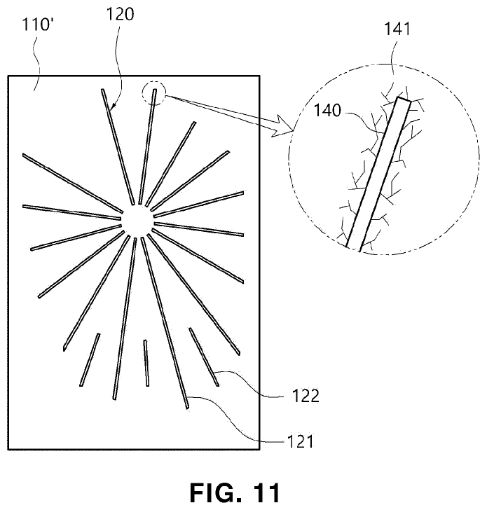

Meanwhile, if two or more antennas with different uses are provided on the electromagnetic wave- and magnetic field-absorbing-and-shielding sheet 100′, antenna performance may deteriorate due to the introduction of the eddy current reduction pattern part 120 described above. To prevent this, as shown in FIGS. 10 and 11, in an embodiment of the present invention, the eddy current reduction pattern part 120 may include a first eddy current reduction pattern part 121 and a second eddy current reduction pattern part 122.

First, the first eddy current reduction pattern part 121 may an eddy current reduction pattern part 120 formed to intersect both a first antenna 220 and a second antenna 230 constituting an antenna unit 200, 200′. In this case, as shown in FIGS. 10 and 11, the first eddy current reduction pattern part 121 may be formed to extend to have a relatively long length compared to the second eddy current reduction pattern part 122 to be described later, so that it may be arranged to intersect both the first antenna 220 and the second antenna 230. Through this, the magnetic field shielding sheet 100 according to an exemplary embodiment of the present invention can reduce the influence of eddy currents on the plurality of antennas 220 and 230 with only the first eddy current reduction pattern part 121, which has a predetermined area and is formed in a single shape.

Next, the second eddy current reduction pattern part 122 may be formed to intersect only one antenna of the first antenna 220 and the second antenna 230. In this case, as shown in FIGS. 10 and 11, the second eddy current reduction pattern part 122 can reduce the influence of eddy currents on a local region that is difficult to cover with only the first eddy current reduction pattern part 121, which covers a wide region.

Meanwhile, Korean patent application numbers 10-2020-0073631, 10-2021-0022412 and 10-2021-0050568 by the applicant of the present invention are inserted by reference in their entirety to the present invention in relation to the magnetic field shielding unit 110′ including a plurality of magnetic layers having at least one eddy current reduction pattern part 120.

Meanwhile, in order to offset the reflection caused by the shielding of electromagnetic waves or magnetic fields in the magnetic layers 111, 112, 113, and to quickly transfer heat that may be generated from electromagnetic wave-absorbing adhesive members described later to the outside, for the magnetic layers 111, 112, and 113, it may be advantageous to use a soft magnetic alloy ribbon sheet in which cracks do not occur or an eddy current reduction pattern part is provided.

Next, the electromagnetic wave-absorbing adhesive members 114, 115 disposed between the plurality of magnetic layers 111, 112, 113 described above will be described.

The electromagnetic wave-absorbing adhesive member 114, 115 is arranged between the adjacent magnetic layers 111, 112, 113 and functions to fix the adjacent magnetic layers 111, 112, 113, and to absorb electromagnetic waves that have transmitted the magnetic layers 111, 112, 113 or are reflected from the magnetic layers 111, 112, 113.

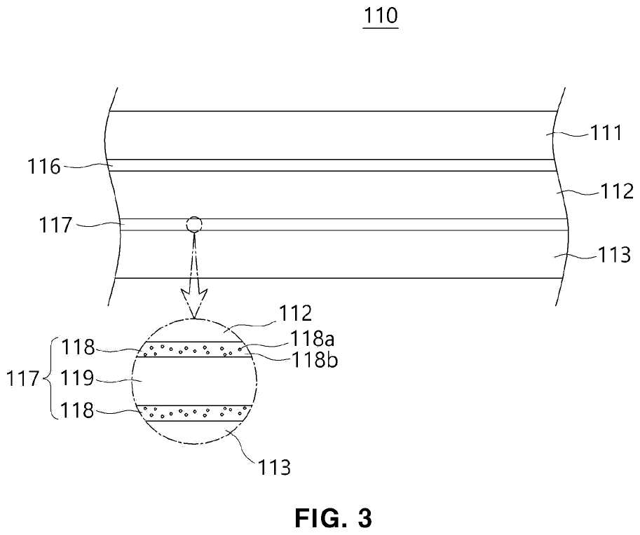

The electromagnetic wave-absorbing adhesive member 114, 115 is not limited in the case of members designed to have a predetermined adhesive performance and electromagnetic wave absorbing performance at the same time, and may be, for example, made of an electromagnetic wave-absorbing adhesive layer in which an electromagnetic wave absorber 114b is dispersed in a binder matrix 114a as shown in FIG. 2 or the electromagnetic wave-absorbing adhesive member 116, 117 may be an electromagnetic wave-absorbing double-sided tape having, on both surfaces of the substrate 119, an electromagnetic wave-absorbing adhesive layer 118 in which an electromagnetic wave absorber 118b is dispersed in a binder matrix 118a as shown in FIG. 3.

The binder matrix 114a, 118a may be formed of a known binder resin having adhesive performance. Specifically, the binder resin may be a mixture of one or two or more types of alkyd resin, epoxy resin, urethane resin, vinyl chloride resin, acrylic resin, silicone resin, fluorine resin, polyester resin, phenol resin, melamine resin, and the like. In addition, the binder matrix 114a, 118a may further include a known curing agent and curing accelerator for curing these binder resins. Alternatively, the binder matrix 114a, 118a may include or be made of natural rubber, butyl rubber, chloropropylene rubber, silicone rubber, etc., thereby helping to improve electromagnetic absorbing performance.

In addition, the electromagnetic wave absorber 114b, 118b may include known materials with electromagnetic wave absorbing performance without limitation, and for example, may include any one or more of dielectric powder, magnetic powder, and conductor powder. In the case of the dielectric powder or magnetic powder, there is no limitation in the case of a material that causes part of electromagnetic energy to be absorbed and extinguished as thermal energy due to the hysteresis caused by time delay between an external electromagnetic field and polarization induced inside the dielectric or magnetic material, and for example, the dielectric powder may be advantageous in a material with a high dielectric loss coefficient, and as a specific example, at least one type of barium titanate (BaTiO₃), strontium barium tantalate (SrBi₂Ta₂O₅), PMN-PT, and the like may be used. In addition, the magnetic powder may be a material that causes magnetic loss, and for example, a metal magnetic material or an oxide magnetic material may be used, and preferably, oxide magnetic materials are good, and ferromagnetic ferrite with a hexagonal structure and high coercive force or soft magnetic ferrite with a spinel structure and low coercive force can be used. In addition, the conductor powder converts electromagnetic waves into heat through a conductive current that flows when an electric field is applied to the medium, and materials with high conductive loss may be advantageous, and for example, carbon-based materials such as carbon black and carbon fiber or metal materials such as nickel chromium and chromium may be advantageous.

When the electromagnetic wave absorber 114b, 118b is in power form, the particle diameter may be 10 nm to 10 μm, but is not limited thereto, and may be appropriately changed considering the thickness of the electromagnetic wave-absorbing adhesive layer. In addition, the content of the electromagnetic wave absorber 114b, 118b may be contained in an amount of 10 to 300 parts by weight based on 100 parts by weight of the binder matrix 114a, 118a.

In addition, the shape of the electromagnetic wave absorber 114b, 118b may be generally spherical, but is not limited thereto, and may be a plate shape, a fiber shape, a rod shape, or an atypical shape.

In addition, the thickness of the electromagnetic wave-absorbing adhesive layer may be 3 to 20 μm, but is not limited thereto.

Meanwhile, when the electromagnetic wave-absorbing adhesive member 116, 117 is in the form of electromagnetic wave-absorbing double-sided tape, the substrate 119 may be a known film for supplementing mechanical strength, for example, a PET film.

Alternatively, the electromagnetic wave-absorbing adhesive member may be in the form of electromagnetic wave-absorbing double-sided tape, and the substrate may be an electromagnetic wave-absorbing substrate and may have a structure in which an adhesive layer or an electromagnetic wave-absorbing adhesive layer is provided on both surfaces of the electromagnetic wave-absorbing substrate. In this case, the electromagnetic wave-absorbing substrate may be a metal foil, a polymer substrate in which a metal film is arranged on one or both surfaces, or a polymer substrate in which an electromagnetic wave absorber is dispersed therein. The metal foil or the metal film may be formed of a metal material known to have electromagnetic wave absorbing performance or electromagnetic wave shielding performance without limitation, and for example, may be formed of a metal material such as aluminum, copper, gold, silver, platinum, nickel, or nickel chromium.

In addition, the electromagnetic wave-absorbing substrate may have a structure in which a plurality of mountain-shaped or pyramid-shaped protrusions are formed on one or both surfaces, thereby improving electromagnetic absorption levels or having broadband characteristics. Specifically, a structure in which a plurality of mountain-shaped protrusions are formed may be a structure in which mountains and valleys are formed continuous in one direction in a plane and formed alternately in another direction in the plane perpendicular to the one direction. In addition, the pyramid-shaped protrusion may be a polypyramid protrusion such as a tetrahedron or a square pyramid, or a conical protrusion, and there is no limit to specific formation patterns such as regular formation in the plane, irregular formation, or only in any area.

A protection part 160 for protecting the exposed magnetic layer 111 may be further provided on one surface of the electromagnetic wave- and magnetic field-absorbing-and-shielding unit 110, 110′ described above. As the protection part 160, a known protection member may be used without limitation, and for example, the protection part may be formed by forming a first adhesive layer 162 on one surface of a protective film 161, and the protective film 161 may be fixed to one surface of the electromagnetic wave- and magnetic field-absorbing-and-shielding unit 110 via the first adhesive layer 162. The protective film 161 may be a known polymer film, and examples thereof may include polyethylene, polypropylene, polyimide, crosslinked polypropylene, nylon, polyurethane-based resin, acetate, polybenzimidazole, polyimide amide, polyetherimide, polyphenylene sulfide (PPS), polyethylene terephthalate (PET), polytrimethylene terephthalate (PTT), polybutylene terephthalate (PBT), polyvinylidene fluoride (PVDF), polytetrafluoroethylene (PTFE), polychlorotrifluoroethylene (PCTFE), polyethylene tetrafluoroethylene (ETFE), and the like, which may be used alone or in combination. In addition, the protective film 161 may have a thickness of 1 to 100 μm, preferably 10 to 30 μm, but is not limited thereto.

In addition, the first adhesive layer 162 may be a layer formed of a known adhesive, and its material may be a mixture of one or two or more types of alkyd resin, epoxy resin, urethane resin, vinyl chloride resin, acrylic resin, silicone resin, fluorine resin, polyester resin, phenol resin, melamine resin, and the like. Meanwhile, in order to achieve more improved electromagnetic wave absorbing performance, the first adhesive layer 162 may also further include an electromagnetic wave absorber. In addition, the first adhesive layer 140b may have a thickness of 3 to 30 μm, but is not limited thereto, and may be practiced by changing it according to the purpose.

In addition, the electromagnetic wave- and magnetic field-absorbing-and-shielding unit 110, 110′ may further include an attachment part 170 on an opposite surface facing the surface on which the protection part 160 is formed. The attachment part 170 is for fixing the electromagnetic wave- and magnetic field-absorbing-and-shielding unit to an attachment target surface of a target, and may include a known adhesive layer or sticky layer. For example, the attachment part 170 may include a second adhesive layer 172 and a third adhesive layer 173 formed on both surfaces of a base film 171, respectively, or may be formed only of an adhesive layer by omitting the base film 171. Here, since the material of the second adhesive layer 172 and the third adhesive layer 173 may be a known adhesive, detailed description in the present invention will be omitted. In addition, the third adhesive layer 173 may be composed of a sticky layer to improve reworkability on an attachment target surface, and the adhesive layer may be formed of a known sticky component such as acrylic. In addition, since the material of the base film 171 is the same as the description of the material of the protective film described above, detailed description will be omitted. In addition, the thickness of the second adhesive layer 172 and the third adhesive layer 173 may each independently be 5 to 50 μm. In addition, the thickness of the base film 171 may be 10 to 100 μm.

The electromagnetic wave- and magnetic field-absorbing-and-shielding sheet 100, 100′ according to an exemplary embodiment of the present invention described above is provided on an antenna unit including at least one antenna to implement an antenna module.

For example, the antenna may be any one of a wireless power transmission antenna, a near field communication antenna, and a magnetic secure transmission antenna. In addition, two or more antennas provided in the antenna unit may have two or more antennas with the same function or one or two or more antennas with different functions.

In addition, since the antenna may have the shape, structure, and size of a known antenna, the present invention is not particularly limited thereto.

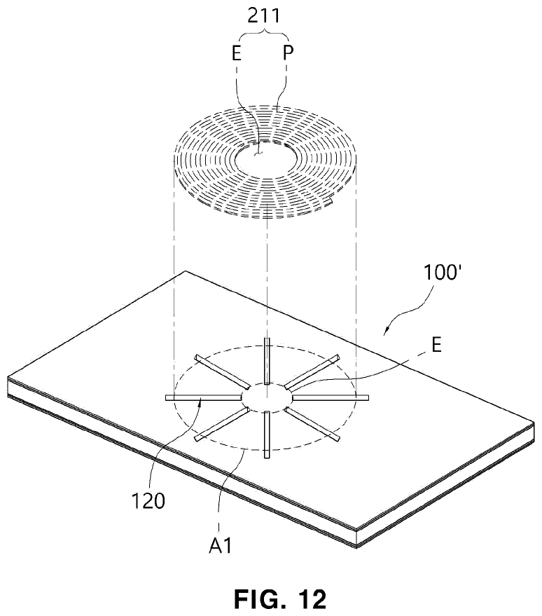

Meanwhile, looking in detail at the arrangement between the antenna unit and the electromagnetic wave- and magnetic field-absorbing-and-shielding sheet 100′, where the magnetic layer includes at least one eddy current reduction pattern part 120, in the case of such an eddy current reduction pattern part 120, as shown in FIG. 12, the eddy current reduction pattern part 120 may be formed only on a partial area corresponding to the pattern part of the antenna 211 based on the central point of the internal hollow portion E of the antenna 211, and the partial area in which the pattern part P of the antenna 211 is arranged may be, for example, an arrangement region A1 shown in FIG. 12.

In addition, the eddy current reduction pattern part 120 formed over a partial area corresponding to the pattern part P of the antenna 211 may be formed radially, for example. However, the form of arrangement of the eddy current reduction pattern part 120 in the electromagnetic wave- and magnetic field-absorbing-and-shielding sheet 100′ according to an exemplary embodiment of the present invention is not limited thereto, and as long as it is formed at a position corresponding to the antenna 211, the eddy current reduction pattern part 120 may be formed in various ways.

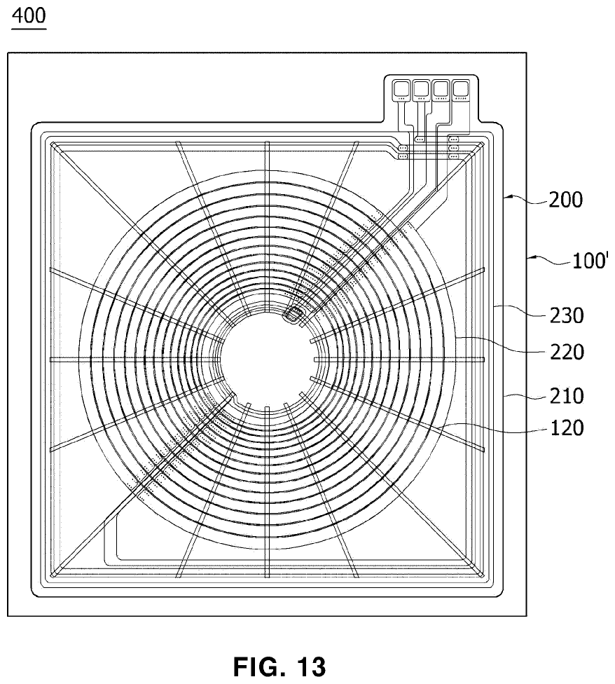

For example, as shown in FIG. 13, an antenna module 400 may include an antenna unit 200 including a first antenna 220, and an electromagnetic wave- and magnetic field-absorbing-and-shielding sheet 100′, arranged on one surface of the antenna unit 200, that absorbs and shields the electromagnetic waves and magnetic field, focuses the magnetic field in the direction of the need, and minimizes the Joule heat generated by the eddy current.

Here, the antenna unit 200 may be a combo antenna unit including a second antenna 230 disposed to surround the outer periphery of the first antenna 220 in addition to a first antenna 220, and the first antenna 220 and the second antenna 230 may be antenna patterns patterned on one surface of a circuit board 210. Here, the first antenna 220 may be, for example, an antenna for wireless power transmission (WPT), the second antenna 230 may be an antenna for wireless communication, for example, an NFC antenna.

In this way, if the antenna unit 200 is formed as a combo antenna unit, the eddy current reduction pattern part 120 may be formed in a region corresponding to a region in which the first antenna 220 and the second antenna 230 are arranged among the entire regions of the electromagnetic wave- and magnetic field-absorbing-and-shielding unit 110′. Alternatively, it may be formed only in a region corresponding to a region in which the first antenna 220 is arranged, unlike the one shown in FIG. 13. That is, the eddy current reduction pattern part 120 may not be formed in the remaining region of the combo antenna unit 200 except for a region corresponding to a region in which the first antenna 220 is arranged. In particular, the eddy current reduction pattern part 120 may not be formed in a region corresponding to a region in which the second antenna 230 is arranged.

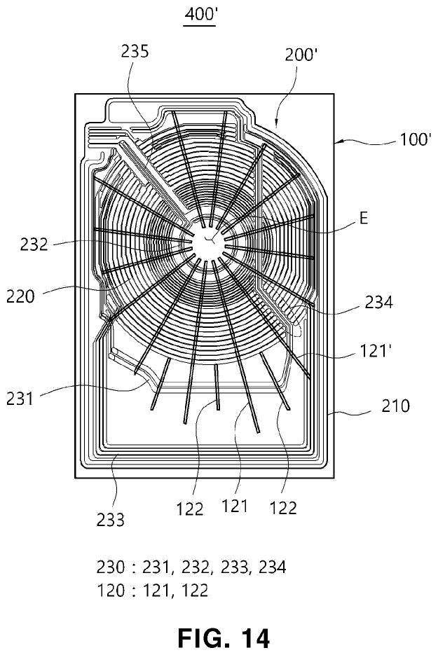

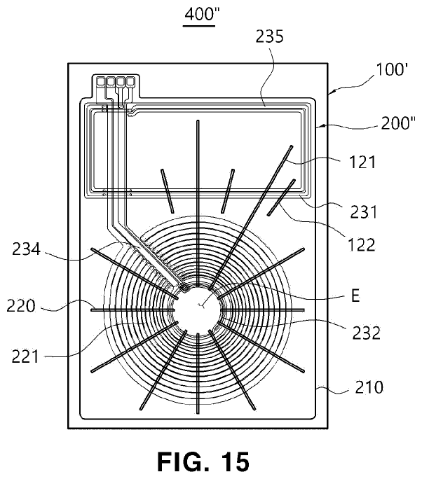

Next, with reference to FIGS. 14 and 15, an antenna unit 200′, 200″ to which the electromagnetic wave- and magnetic field-absorbing-and-shielding sheet 100′ in which the eddy current reduction pattern part 120 has the first eddy current reduction pattern part 121 and the second eddy current reduction pattern part 122 as shown in FIGS. 10 and 11 is applied will be described.

In an embodiment of the present invention, the antenna unit 200′, 200″ may be a combo antenna unit including a first antenna 220 and a second antenna 230, as described above. Here, as shown in FIGS. 14 and 15, the first antenna 220 may include a radiation pattern 221 disposed on one side of a circuit board 210 and wound multiple times around a central portion E having a predetermined area. In addition, the second antenna 230 may include a first pattern 231, a second pattern 232, and a connection pattern 233, 234.

In this case, the first pattern 231, the second pattern 232, and the connection pattern 233, 234 may each refer to a portion of the entire second antenna 230. And, the first pattern 231, the second pattern 232, and the connection pattern 233, 234 may be formed to be physically connected to each other, or each may be formed independently.

In addition, the first pattern 231, the second pattern 232, and the connection pattern 233, 234 may all be formed with the same type of antenna, or may be formed by mixing different types of antennas. For example, the above-described first pattern 231, second pattern 232, and connection pattern 233, 234 may all be formed as NFC antennas, or may be formed by mixing an NFC antenna and an MST antenna.

Further, the second antenna 230 may be formed to include all of the first pattern 231, the second pattern 232, and the connection pattern 233, 234, or be formed to include only some of the above-described patterns.

Specifically, the first pattern 231 is a portion disposed outside the above-described radiation pattern 221 among the second antenna 230, and as shown in the drawing, may be arranged to be spaced apart from the radiation pattern 221 by a predetermined distance. In this case, the first pattern 231 may be placed in a space between the radiation pattern 221 and the outer edge of the shielding part 110 to improve wireless communication sensitivity in that space.

And, the first pattern 231 may be extended in a straight line form as shown in the drawing, may be extended in a circularly wound form similar to the radiation pattern 221, or may be formed to include both straight line and circular patterns. Meanwhile, the first pattern 231 shown in the drawing is only an example of the first pattern 231, and the first pattern 231 may have any shape as long as it is a part of the patterns of the second antenna 230 and is arranged outside the first antenna 220.

Next, the second pattern 232 is arranged inside the radiation pattern 221, that is, in a central portion E of the first antenna 220, and may be arranged in a wound form to form a circular loop similar to the first antenna 220.

In this case, the second pattern 232 may be arranged to increase sensitivity, for example, wireless communication sensitivity, by the second antenna in a region adjacent to the central portion E.

And, unlike the first pattern 231 and the second pattern 232 described above, the connection pattern 233, 234 may be arranged to overlap the radiation pattern 221 of the first antenna 220.

In an embodiment of the present invention, the connection pattern 233, 234 may refer to some regions extending in the radial direction of the radiation pattern 221 as shown in FIGS. 14 and 15 among various patterns of the second antenna 230 overlapping with the first antenna 220.

As a specific example, the connection pattern 233, 234 may include a first connection pattern 233 whose one end is connected to the above-described first pattern 231. In this case, the first connection pattern 233 may be disposed in a form that traverses the radiation pattern 221 to connect the first pattern 231 to a terminal or another pattern directly without bypassing the radiation pattern 221 on the circuit board 210 having a limited area.

As another example, the connection pattern 233, 234 may include a second connection pattern 234 having one end connected to the second pattern 232. In this case, the second connection pattern 234 may be arranged to traverse the radiation pattern 221 to connect the second pattern 232 disposed inside the radiation pattern 221 to a terminal or another pattern.

Meanwhile, referring to FIGS. 14 and 15, a third pattern 235 may be arranged in a region adjacent to the outer edge of the electromagnetic wave- and magnetic field-absorbing-and-shielding sheet 100′. This third pattern 235 is a non-limiting example and may be disposed to transfer heat emitted from the antenna unit 200′, 200″ to a separate heat dissipation member (not shown) or a sensor member (not shown) for detecting temperature.

Looking at the specific positional relationship between the antenna unit 200′, 200″ and the eddy current reduction pattern part 120, as shown in FIGS. 14 and 15, the first eddy current reduction pattern part 121 may include linear patterns in which a plurality of linear patterns are radially arranged around the central portion E of the first antenna 220. Through this, the first eddy current reduction pattern part 121 may intersect both the first antenna 220 and the second antenna 230, as described above. Specifically, the first eddy current reduction pattern part 121 may intersect the radiation pattern 221 of the first antenna 220 and at the same time intersect at least one of the first pattern 231 and the second pattern 232 of the second antenna 230.

For example, the first eddy current reduction pattern part 121 may intersect both the first pattern 231 and the second pattern 232 formed on the outside and inside of the radiation pattern 221, and through this, even with the first eddy current reduction pattern part 121, it is possible to reduce the overall influence of eddy currents on respective parts 231 and 232 of the second antenna 230, which are positioned spaced apart from each other with the first antenna 220 interposed therebetween.

However, the application of the electromagnetic wave- and magnetic field-absorbing-and-shielding sheet 100′ according to an exemplary embodiment of the present invention is not limited to this, and depending on the design, the first eddy current reduction pattern part 120 may be arranged to intersect only one of the first pattern 231 and the second pattern 232.

Meanwhile, referring back to FIGS. 14 and 15, the first eddy current reduction pattern part 121 may be formed to be located to avoid a region where the first antenna 220 and the second antenna 230 overlap with each other.

For example, as shown in the drawing, the first eddy current reduction pattern part 121 may be disposed in a region other than in some regions in which the first connection pattern 233 connected to the first pattern 231 is arranged or in some regions in which the second connection pattern 234 connected to the second pattern 232 is arranged, among the radiation pattern 221.

In this regard, the inventor of the present invention conducted an experiment by comparing the case where the eddy current reduction pattern part 120 is arranged to overlap the connection pattern 233, 234 with the case where the eddy current reduction pattern part 120 is arranged to avoid the connection pattern 233, 234. As a result of the experiment, it was confirmed that the performance such as recognition distance of the NFC antenna corresponding to the second antenna was deteriorated when the eddy current reduction pattern part 120 was arranged to overlap the connection pattern 233, 234, whereas it was confirmed that the performance of the NFC antenna corresponding to the second antenna 230 was improved when it was arranged to avoid the connection pattern 233, 234.

As such, the electromagnetic wave- and magnetic field-absorbing-and-shielding sheet 100′ according to an exemplary embodiment of the present invention may arrange the eddy current reduction pattern part 120 to avoid a region where the first antenna and the second antenna overlap with each other, thereby preventing antenna performance from being deteriorated due to the introduction of the eddy current reduction pattern part. Meanwhile, the second eddy current reduction pattern part 122 may be arranged between at least one pair of first eddy current reduction pattern parts 121 arranged adjacent to each other and be arranged to intersect the pattern of the second antenna 230.

As a specific example, the second eddy current reduction pattern part 122 may be arranged to partially intersect only the first pattern 231 disposed outside the radiation pattern 221 as shown in FIGS. 14 and 15, thereby reducing the influence of eddy current on the antenna pattern arranged in a region between the first eddy current reduction pattern parts 121.

Further, in the drawing, the drawing shows that the second eddy current reduction pattern part 122 is formed only on the outside of the radiation pattern 221, but the second eddy current reduction pattern part 122 may be arranged between the first eddy current reduction pattern parts 121, and may be formed to intersect the second pattern 232 provided inside the radiation pattern 221.

In addition, the second eddy current reduction pattern part 122 may be arranged in a plurality of regions requiring eddy current reduction on the electromagnetic wave- and magnetic field-absorbing-and-shielding unit, as shown in the drawing, and depending on the size of the space formed between the plurality of first eddy current reduction pattern parts 121, the second eddy current reduction pattern parts 122 may have different areas.

As such, the electromagnetic wave- and magnetic field-absorbing-and-shielding sheet 100′ according to an exemplary embodiment of the present invention includes a second eddy current reduction pattern part 122 having relatively small area loss, so that the number of first eddy current reduction pattern parts 121 that are formed in a relatively large area to reduce the magnetic permeability of the electromagnetic wave- and magnetic field-absorbing-and-shielding unit 110 can be minimized, while partially supplementing the effect of eddy current reduction to secure antenna performance.

Meanwhile, although not shown in FIGS. 13 to 15, the antenna unit 200, 200′, 200″ may further include a magnetic secure transmission (MST) antenna.

In addition, the antenna module 400, 400′, 400″ may be implemented as receiving modules in which the first antenna 220 or the first antenna 220 and the second antenna 230 act as receiving antennas for receiving predetermined signals, or may be implemented as transmission modules in which the first antenna 220 or the first antenna 220 and the second antenna 230 transmit signals to the outside.

In addition, an electronic device employing the above-described electromagnetic wave- and magnetic field-absorbing-and-shielding sheet 100, 100′ can be implemented. The electronic devices may be electronic devices such as various displays, including portable terminal devices such as smartphones and tablet PCs.

Although exemplary embodiments of the present invention have been described above, the idea of the present invention is not limited to the embodiments set forth herein. Those of ordinary skill in the art who understand the idea of the present invention may easily propose other embodiments through supplement, change, removal, addition, etc. of elements within the scope of the same idea, but the embodiments will be also within the idea scope of the present invention.

What is claimed is:

1. An electromagnetic wave- and magnetic field-absorbing-and-shielding sheet, comprising:
an electromagnetic wave- and magnetic field-absorbing-and-shielding unit, having:
a plurality of magnetic layers stacked to shield electromagnetic waves and magnetic fields; and
an electromagnetic wave-absorbing adhesive member, which is arranged between the adjacent magnetic layers so as to absorb electromagnetic waves that have transmitted the magnetic layers or are reflected from the magnetic layers, and fixes the adjacent magnetic layers.

2. The electromagnetic wave- and magnetic field-absorbing-and-shielding sheet of claim 1, wherein the plurality of magnetic layers comprise one or more of a soft magnetic alloy ribbon sheet, a soft magnetic alloy ribbon sheet split into multiple pieces, and a soft magnetic alloy ribbon sheet with at least one eddy current reduction pattern part formed.

3. The electromagnetic wave- and magnetic field-absorbing-and-shielding sheet of claim 2, wherein the eddy current reduction pattern part is a crack part in which a magnetic material constituting a magnetic layer in a predetermined region is split into a plurality of pieces, or is a penetration part penetrating the predetermined region.

4. The electromagnetic wave- and magnetic field-absorbing-and-shielding sheet of claim 1, wherein the electromagnetic wave-absorbing adhesive member is made of an electromagnetic wave-absorbing adhesive layer in which an electromagnetic wave absorber is dispersed in a binder matrix or is an electromagnetic wave-absorbing double-sided tape having, on both surfaces of a substrate, an electromagnetic wave-absorbing adhesive layer in which an electromagnetic wave absorber is dispersed in a binder matrix.

5. The electromagnetic wave- and magnetic field-absorbing-and-shielding sheet of claim 1, wherein the electromagnetic wave-absorbing adhesive member is an electromagnetic wave-absorbing double-sided tape in which an adhesive layer is provided on both surfaces of an electromagnetic wave-absorbing substrate.

6. The electromagnetic wave- and magnetic field-absorbing-and-shielding sheet of claim 5, wherein the adhesive layer is an electromagnetic wave-absorbing adhesive layer in which an electromagnetic wave absorber is dispersed in a binder matrix.

7. The electromagnetic wave- and magnetic field-absorbing-and-shielding sheet of claim 5, wherein the electromagnetic wave-absorbing substrate is a metal foil, a polymer substrate in which a metal film is arranged on one or both surfaces, or a polymer substrate in which an electromagnetic wave absorber is dispersed therein.

8. The electromagnetic wave- and magnetic field-absorbing-and-shielding sheet of claim 7, wherein the electromagnetic wave-absorbing substrate has a plurality of mountain-shaped or pyramid-shaped protrusions on one or both surfaces.

9. The electromagnetic wave- and magnetic field-absorbing-and-shielding sheet of any one of claims 4, 6, and 7, wherein the electromagnetic wave absorber comprises any one or more of dielectric powder, magnetic powder, and conductor powder.

10. The electromagnetic wave- and magnetic field-absorbing-and-shielding sheet of claim 1, wherein the thickness of the magnetic layer is 15 to 35 μm, and the thickness of the electromagnetic wave-absorbing adhesive member is 3 to 50 μm.

11. An antenna module, comprising:
an antenna unit equipped with at least one antenna; and
the electromagnetic wave- and magnetic field-absorbing-and-shielding sheet according to claim 1 arranged on one surface of the antenna unit.

12. An electronic device comprising the electromagnetic wave- and magnetic field-absorbing-and-shielding sheet according to claim 1.
